(19) United States
(12) Patent Application Publication
(10) Pub. No.: US 2025/0079259 A1
(43) Pub. Date: Mar. 6, 2025

(54) PACKAGE FOR INTEGRATED CIRCUIT WITH HEAT DISSIPATION

(71) Applicant: STMicroelectronics International N.V., Geneva (CH)

(72) Inventors: Jerome LOPEZ, Saint Jean De Moirans (FR); Luc PETIT, Fontaine (FR); Karine SAXOD, Porte de Savoie (FR)

(73) Assignee: STMicroelectronics International N.V., Geneva (CH)

(21) Appl. No.: 18/824,206

(22) Filed: Sep. 4, 2024

(30) Foreign Application Priority Data
Sep. 5, 2023 (FR) 2309295

(51) Int. Cl. H01L 23/373; H01L 21/48; H01L 23/00; H01L 23/31; H01L 23/498

(52) U.S. Cl. CPC H01L 23/3736; H01L 21/4882; H01L 23/3107; H01L 24/32; H01L 24/83; H01L 23/498; H01L 24/16; H01L 24/33; H01L 24/73; H01L 2224/16227; H01L 2224/32225; H01L 2224/32245; H01L 2224/33181; H01L 2224/73204

(57) ABSTRACT

An integrated circuit package includes a support plate having a mounting face. An electronic chip, having a rear face and a front face, is mounted on the mounting face with the front face electrically connected to the mounting face of the support plate. A deformable thermally conductive film covers at least one portion of the rear face of the electronic chip so that the film is in contact with the rear face.

### PRIORITY CLAIM

This application claims the priority benefit of French Application for Patent No. 2309295, filed on Sep. 5, 2023, the content of which is hereby incorporated by reference in its entirety to the maximum extent allowable by law.

### TECHNICAL FIELD

Implementations and embodiments relate to the field of microelectronics, particularly the field of integrated circuit packaging and more particularly heat dissipation structures in integrated circuit packages.

Heat dissipation structures are typically provided to dissipate the heat generated by a face of the electronic chip containing integrated circuits present in a package.

These heat dissipation structures conventionally comprise a heat sink, for example a copper plate, attached on this face of the electronic chip by use of a thermal interface material layer, for example a mixture of silicon and copper, well known by the person skilled in the art.

In particular, the thermal interface material layer makes it possible to perform a heat transfer between the chip and the heat sink in order that the heat sink can dissipate the heat outward of the package and so that the temperature of the integrated circuits does not reach a value leading to their degradation.

That said, the thermal interface material is a weak spot of the thermal chain since it has a thermal conductivity lower than the heat sink.

In this regard, the thickness of the thermal interface material layer should be reduced to improve the heat dissipation of the package. However, the adhesive power of the thermal interface material layer is known to be limited and reducing the thickness of the thermal interface material layer may deteriorate the mechanical strength of the heat sink on the chip.

Furthermore, the thermal material layer may deteriorate throughout the life of the package and may have imperfections such as hollows that may affect the mechanical strength of the heat sink and degrade the thermal performances of the package.

Therefore, there is a need to improve the thermal performances of the integrated circuit package.

### SUMMARY

In an embodiment, an integrated circuit package comprises: a support plate having a mounting face; an electronic chip having a rear face and a front face, the electronic chip being mounted on the mounting face so that the front face is electrically connected to the mounting face of the support plate; and a deformable thermally conductive film, for example made of metal, configured to cover and be in contact with at least one portion of the rear face of the chip.

The deformable thermally conductive film adapts to the shape of the chip or of other components mounted on the support plate.

Therefore, such a film does not require thermal interface material to be attached to the chip and therefore makes it possible to improve the heat dissipation within the package. The film also guarantees a mechanical strength throughout the life of the package, which prevents the risk of degradation of the thermal performances of the package.

Moreover, the film in the case of total covering of the chip may act as the heat sink while advantageously being thinner than a prior art heat sink. Thus, the cost of manufacturing the film is lower than the heat sink and makes it possible to make the package smaller in that case.

Consequently, the package according to this aspect benefits from improved thermal performances throughout its life.

According to one embodiment, the thermally conductive film is welded to at least one portion of the rear face of the chip.

The film is secured on the rear face of the chip and makes it possible to directly discharge the heat without intermediaries between the film and the chip such as the thermal interface material layer.

According to one embodiment, the thermally conductive film is attached on at least one portion of the rear face of the chip using an adhesive.

The adhesive is typically a glue or a double-sided adhesive tape making it possible to attach the film on the rear face of the chip while having a thermal conductivity better than the thermal interface material for a given thickness.

According to one embodiment, the support plate comprises an opening passing through the thickness of the support plate until opening onto the mounting face, the thermally conductive film further covering the mounting face and sealing said opening.

The opening forms a passage in the support plate making it possible to perform vacuum lamination during the manufacture of the package. Vacuum lamination is a technique adapted to attach the film on the chip so as to avoid the presence of air between the adhesive and the rear face of the chip and consequently improves the securing of the film on the chip.

According to one embodiment, the package comprises a molding resin disposed on the mounting face of the support plate so that the resin coats the chip and uncovers the rear face of the chip, the thermally conductive film also being configured to cover an upper face of the molding resin.

The film is also compatible with the packages including a molding resin making it possible to protect the electronic chip by leaving the rear face of the chip exposed so that it is in contact with the thermally conductive film.

According to one embodiment, the chip is configured to have hot spots releasing heat during operation, the thermally conductive film being configured to cover the hot spots of the chip.

Thermal simulation tools or, alternatively thermal sensors are used to detect the hot spots, that is to say the areas of the chip that may have temperature spikes during its operation. The positions of these hot spots, once identified, may be taken into account in order to define the shape of the film. Thus, identifying the hot spots of the chip makes it possible to shape the film in such a way that it covers these hot spots while limiting the amount of material used to manufacture the film.

According to one embodiment, the film has a thickness between 5 μm and 0.5 mm.

This film thickness range typically makes it possible to make the package smaller and may be defined according to the choice of material used for the film so as to make it deformable.

According to one embodiment, the modulus of elasticity of the thermally conductive film is between 10⁻⁵ and 100-150 Gpa.

Consequently, a film having these modulus of elasticity values is sufficiently deformable to adapt to the morphology of the chip without risk of detachment.

According to one embodiment, the thermally conductive film also covers the mounting face of the support plate and is connected to thermally conductive elements of the support plate.

The thermally conductive elements such as the weld beads, the interconnection network and the electrical contacts of the plate may advantageously be used to form an additional passage with the film to discharge the heat under the package.

According to one embodiment, the package comprises a component mounted on the mounting face of the support plate, wherein the thermally conductive film also covers the mounting face of the support plate and comprises an opening capable of containing the component.

Openings may be made in the thermally conductive film according to the design constraints of the package related for example to the presence of components mounted on the surface. Therefore, such openings make it possible to affix the film on the chip and the mounting face of the plate without covering these components and without subsequently hindering their operation.

According to one embodiment, the thermally conductive film also covers at least one portion of the side face of the electronic chip.

The film may for example cover at least one portion of the rear face of the chip and extend up to the edges of the chip to optimize the dissipation of the heat.

According to another aspect, a method is proposed for manufacturing an integrated circuit package including a support plate having a mounting face, the method comprising: mounting on the mounting face the support plate of an electronic chip having a rear face and a front face so that the front face is electrically connected to the mounting face; and covering a portion of the rear face of the chip by a deformable thermally conductive film so that the film is in contact with the rear face.

According to one implementation, covering a portion of the rear face by the thermally conductive film comprises attaching the film on at least one portion of the rear face of the chip using an adhesive.

According to one implementation, the method comprises forming an opening passing through the thickness of the support plate until opening onto the mounting face, wherein the attachment of the film on at least one portion of the rear face is performed by using the opening to create a vacuum between the film and the support plate so that the film covers the mounting face and seals said opening.

According to one implementation, the film has a thickness between 5 μm and 0.5 mm.

According to one implementation, the thermally conductive film is a metal.

According to one implementation, the modulus of elasticity of the thermally conductive film is between 10⁻⁵ and 100-150 Gpa.

According to one implementation, covering a portion of the rear face by the thermally conductive film comprises chemical vapor deposition on at least one portion of the rear face of the chip.

According to one implementation, the method comprises forming a molding resin on the mounting face of the support plate so that the molding resin coats the chip and uncovers the rear face, the thermally conductive film covering an upper face of the molding resin.

According to one implementation, the method comprises identifying hot spots of the chip by a thermal simulation of the chip during operation, wherein the covering of a portion of the rear face by the thermally conductive film is performed so that the film covers the hot spots of the chip.

According to one implementation, the method further comprises connecting the film to thermally conductive elements of the support plate.

According to one implementation, the method comprises mounting a component on the mounting face of the support plate and forming an opening in the thermally conductive film so that said opening contains the component after said covering of a portion of the rear face by the thermally conductive film.

According to one implementation, the method comprises covering a portion of the side face of the electronic chip by the thermally conductive film at the same time as covering a portion of the rear face by the film.

### BRIEF DESCRIPTION OF THE DRAWINGS

Other advantages and features of the invention will become apparent upon examining the detailed description of non-limiting embodiments and implementations, and from the accompanying drawings wherein:

FIG. 1 schematically illustrates a sectional view of an integrated circuit package;

FIG. 2 schematically illustrates a sectional view of a package;

FIG. 3 schematically illustrates a sectional view of a package;

FIG. 4 schematically illustrates a sectional view of a package;

FIG. 5 schematically illustrates a top view of a package;

FIG. 6 schematically illustrates a sectional view of a package; and

FIGS. 7 to 13 illustrate the steps of a method for manufacturing the integrated circuit packages described above in relation with FIGS. 1 to 6.

### DETAILED DESCRIPTION

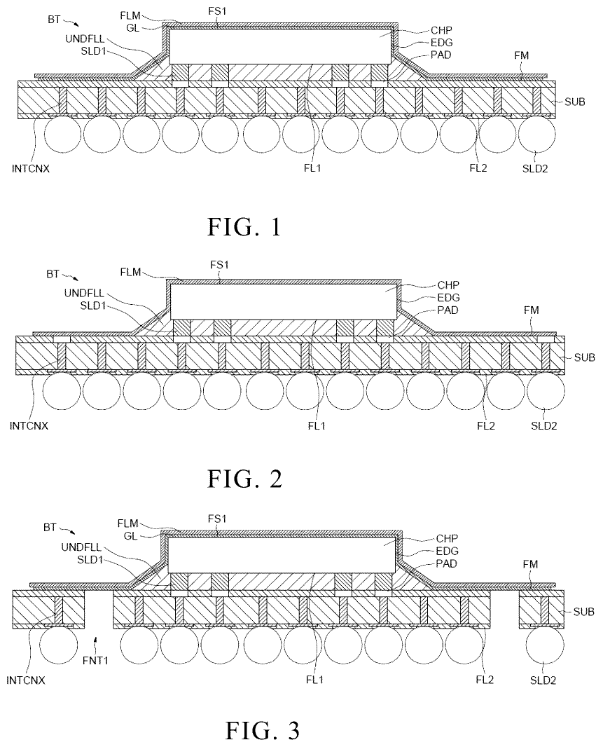

FIG. 1 schematically illustrates a sectional view of an integrated circuit package BT.

The package BT comprises an electronic (integrated circuit—IC) chip CHP containing one or more integrated circuits and a support plate SUB having a mounting face FM. The support plate SUB may be a support substrate for example. Such a support plate SUB may comprise an interconnection network INTCNX and electrical contacts PAD located on the mounting face FM and electrically connected to the interconnection network INTCNX.

The chip CHP comprises a rear face FS1 and a front face FL1 including integrated circuit components, such as transistors for example.

The chip CHP is mounted on the mounting face FM of the support plate SUB according to a “flip chip” type mounting.

More particularly, the front face FL1 of the chip CHP may be electrically connected to the electrical contacts PAD of the support plate SUB by use of weld beads SLD1 embedded in an underfill UNDFLL material known by the person skilled in the art.

Furthermore, the support plate SUB may be equipped with weld beads SLD2 attached on a face of the support plate SUB opposite the mounting face FM and making it possible to connect the package BT to a printed circuit board (not shown in the figure) for example. The interconnection network INTCNX of the support plate SUB is typically configured to electrically couple the electrical contacts PAD to the weld beads SLD2 and pass signals between the electronic chip CHP and circuits of the printed circuit board.

However, the integrated circuits of the chip CHP generate heat that may diffuse by the rear face FS1, and also on the side faces EDG of the chip CHP during the operation of the chip CHP. The heat emitted by the chip CHP contributes to increasing the temperature within the package BT and is likely to degrade the integrated circuits if it exceeds a certain value.

In this regard, the package BT advantageously comprises a deformable thermally conductive film FLM, for example made of metal such as copper (Cu) or aluminum (Al). The film FLM may also be a copper film that has a face coated with nickel (Ni), with a nickel-platinum (NiPd) alloy or also with aluminum.

The film FLM is configured to cover and be in contact with the rear face FS1 of the chip CHP, for example by being attached on this portion of the rear face FS1 using an adhesive GL as illustrated in FIG. 1.

The thermally conductive film FLM adapts to the shape of the chip or of other components mounted on the support plate SUB and may be attached to the chip CHP using an adhesive GL that is thermally conductive.

The thermal performances of the package are thus improved. The film also guarantees a mechanical strength throughout the life of the package, which prevents the risk of degradation of the thermal performances of the package.

Here, the film FLM completely covers the rear face FS1 of the chip CHP and acts as a conventional heat sink by protecting the chip and by dissipating the heat outward of the package BT while being thinner and less expensive than the heat sink of the prior art.

Moreover, the film FLM also covers at least one portion of the side faces EDG of the chip CHP through which the heat may also diffuse and thus makes it possible to optimize the heat dissipation.

Furthermore, the film FLM has a thickness between 5 μm and 0.5 mm. This film thickness range may be defined according to the choice of the material used for the film so as to make it deformable and makes it possible, in the case where the film substitutes for the use of the heat sink, to make the package BT smaller. The person skilled in the art will know how to adapt the thickness of the film depending on the material used in such a way as to make the film deformable.

The thermally conductive film FLM also has a modulus of elasticity between 10⁻⁵ and 100-150 Gpa.

Consequently, a film having these modulus of elasticity values is sufficiently deformable to adapt to the morphology of the chip without risk of detachment of the film, particularly in the case where the film is attached by use of the adhesive GL.

The adhesive GL may be glue such as the non-conductive glue EA6900 marketed by DOW or the electrically conductive glue 2100A marketed by Henkel. The adhesive GL may also be a double-sided adhesive tape such as the adhesive tape PC07 marketed by Boyd. The adhesive GL is preferably thermally conductive and typically offers a better adherence than the thermal interface material.

FIG. 2 schematically illustrates a sectional view of a package BT. The elements in common with the package in FIG. 1 have the same references and will not all be detailed again.

The thermally conductive film FLM is welded to the rear face FS1 of the chip CHP and completely covers the rear face FS1 for example. Alternatively, the thermally conductive film FLM may also have been formed on the rear face FS1 thanks to chemical vapor deposition of a thin metallic layer by sputtering.

The rear face FS1 and the side faces EDG of the chip are therefore directly covered by the film FLM without intermediate layers, thus reducing the thermal chain between the chip CHP and the exterior of the package BT. Consequently, the heat dissipation is improved.

The thermally conductive film FLM is also welded or formed on the mounting face FM of the support plate SUB. The film FLM is connected to thermally conductive elements of the support plate SUB, for example to non-operational electrical contacts PAD, that is to say which are not used to transmit electrical signals, which are coupled to the weld beads SLD2 by the interconnection network INTCNX.

The weld beads SLD2, the interconnection network INTCNX and the electrical contacts PAD may advantageously form an additional passage with the film FLM for dissipating the heat under the package BT and thus contribute to improving the heat dissipation of the package BT.

FIG. 3 schematically illustrates a sectional view of a package BT. The elements in common with the package in FIG. 1 have the same references and will not all be detailed again.

The support plate SUB comprises an opening FNT1 passing through the thickness of the plate SUB until opening onto the mounting face FM.

The film FLM is also attached to the support plate SUB by the adhesive GL so as to cover the plate SUB and to seal the opening FNT1.

The opening FNT1 forms a passage in the support plate SUB making it possible to attach the film FLM thanks to a vacuum lamination performed during the manufacture of the package BT.

Thus, the presence of air is reduced between the adhesive GL and the rear face FS1 and the side faces EDG of the chip CHP and consequently the securing of the film FLM on the chip CHP as well as the heat dissipation are improved.

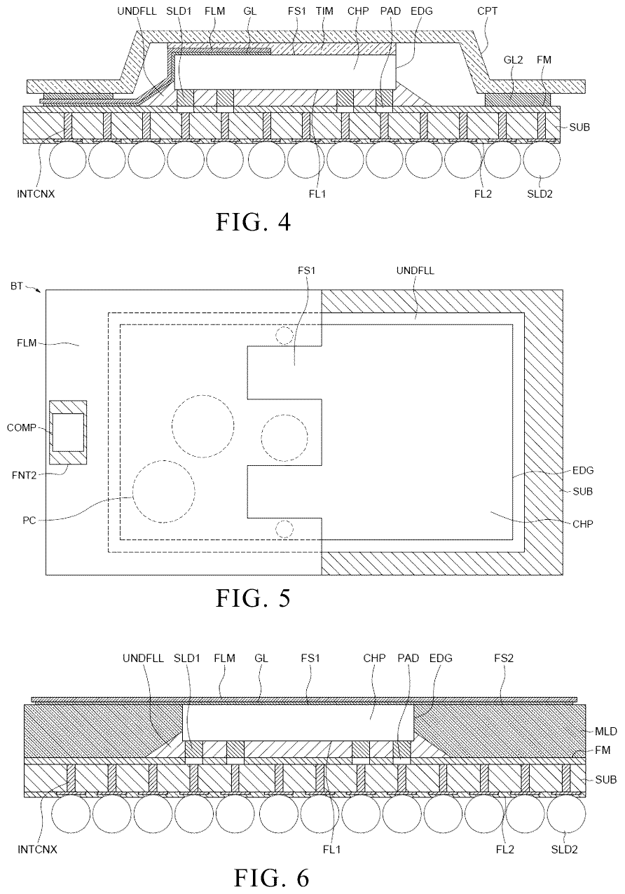

FIG. 4 schematically illustrates a sectional view of a package BT. The elements in common with the package in FIG. 1 have the same references and will not all be detailed again.

The chip CHP may in some cases have during operation hot spots releasing heat in a more localized manner on the rear face FS1 or the side faces EDG of the chip CHP.

The thermally conductive film FLM is attached on the rear face FS1 of the chip CHP and covers a portion of the rear face FS1, particularly the hot spots of the chip CHP located on this portion of the rear face FS1.

The package BT also comprises a heat sink CPT, made of copper for example, attached on the support plate SUB using an adhesive GL2, for example similar to the adhesive GL described above, and attached on the rear face FS1 of the chip CHP and on the film FLM by a thermal interface material TIM layer.

In particular, a first thickness of the thermal interface material TIM layer covers the portion of the rear face FSI which is not covered by the film FLM and a second thickness, lower than the first thickness, of the thermal interface material TIM layer covers the film FLM.

The package BT then benefits from a more efficient heat dissipation on the portion of the chip CHP generating the most heat thanks to the film FLM.

FIG. 5 schematically illustrates a top view of a package BT. The elements in common with the package in FIG. 1 have the same references and will not all be detailed again. The package BT comprises the heat sink CPT and the thermal interface material layer that have not been shown in FIG. 5.

The hot spots PC of the chip CHP shown in FIG. 5 may for example be detected thanks to thermal simulation tools, such as the Simcenter Flotherm software from Siemens, or thermal sensors (not shown).

The positions of these hot spots PC, once identified, may be taken into account in order to define the shape of the film FLM. The film FLM is for example manufactured or formed by chemical vapor deposition so as to cover the hot spots PC while limiting the amount of material of the film FLM.

Moreover, the package BT also comprises a component COMP, such as a passive electronic component or an antenna, on the mounting face FM of the plate SUB and the film FLM comprises an opening FNT2 capable of containing the component COMP.

Openings may indeed be made in the thermally conductive film according to the design constraints of the package BT related for example to the presence of components mounted on the surface. Therefore, such openings make it possible to affix the film on the chip and the mounting face of the plate without covering these components and without subsequently hindering their operation.

FIG. 6 schematically illustrates a sectional view of a package BT. The elements in common with the package in FIG. 1 have the same references and will not all be detailed again.

The package BT comprises a molding resin MLD disposed on the mounting face FM of the support plate SUB so that the resin MLD coats (e.g., encapsulates) the chip CHP and uncovers the rear face FS1. The resin MLD is typically an epoxy resin mixed with vitreous silica or metal oxides such as alumina.

The thermally conductive film FLM is attached on the rear face FSI of the chip CHP using the adhesive GL such as described above in relation with FIG. 1 and is also attached on an upper face FS2 of the molding resin MLD encapsulation using the adhesive GL.

The film FLM is also compatible with molded packaging packages including a molding resin making it possible to protect the electronic chip by leaving the rear face of the chip exposed so that the latter is in contact with the thermally conductive film.

The resin MDL may also be heat conductive, particularly when the resin contains metal oxides and makes it possible to transfer the heat generated by the side faces EDG of the chip CHP towards the film FLM.

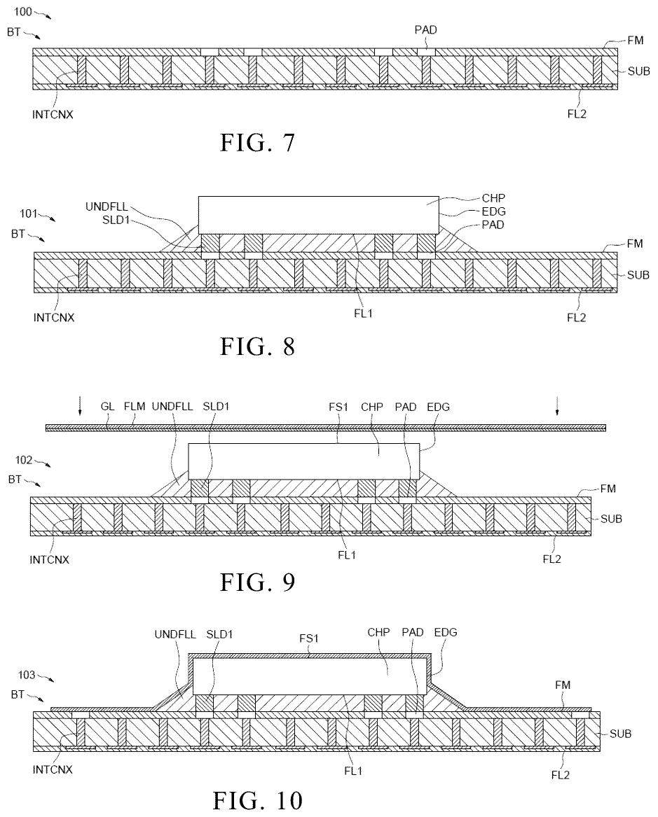

FIGS. 7 to 13 illustrate the steps of a method for manufacturing the integrated circuit packages described above in relation with FIGS. 1 to 6.

FIG. 1 illustrates a step 100 of obtaining a support plate SUB comprising a mounting face FM. The support plate SUB comprises an interconnection network INTCNX and electrical contacts PAD formed on the mounting face FM and electrically connected to the interconnection network INTCNX.

Additional electrical contacts PAD may be formed on the mounting face FM to make it possible to connect the thermally conductive film such as described above in relation with FIG. 2. These electrical contacts PAD are non-operational electrical contacts that are not used to transmit electrical signals.

FIG. 8 illustrates a step 101 of attaching an electronic chip CHP on the mounting face FM of the plate SUB. The chip CHP comprises a rear face FS1 and a front face FL1 connected to the electrical contacts PAD using weld beads SLD1 embedded in an underfill UNDFLL material.

FIG. 9 illustrates a step 102 of attaching a deformable thermally conductive film FLM on the rear face FS1 and side faces EDG of the chip CHP using an adhesive GL.

The film FLM may be coated with a glue or may be attached to a double-sided adhesive tape for example.

In particular, the film FLM may be pressed against the chip CHP by applying a pressure on the film such that the latter deforms to cover the rear face FSI and the side faces EDG of the chip CHP.

Step 102 of attaching the film FLM may be followed by a step of attaching weld beads SLD2 on a face FL2 of the plate SUB opposite the mounting face FM to obtain the package BT shown in FIG. 1.

FIG. 10 illustrates a step 103 of welding the thermally conductive film FLM as an alternative to step 102 described above in relation with FIG. 9.

The welding of the film FLM more particularly comprises welding the film FLM on the rear face FS1 and on the side faces EDG of the chip CHP.

Moreover, the film FLM is welded on the plate SUB in such a way as to be connected to the additional electrical contacts PAD.

Step 103 may be followed by a step of attaching weld beads SLD2 (not illustrated) on a face FL2 of the plate SUB opposite the mounting face FM to obtain the package BT shown in FIG. 2.

In particular, the weld beads SLD2 and the additional electrical contacts PAD are coupled together by the interconnection network INTCNX of the plate SUB in order to form an additional passage with the film FLM for dissipating the heat under the package BT.

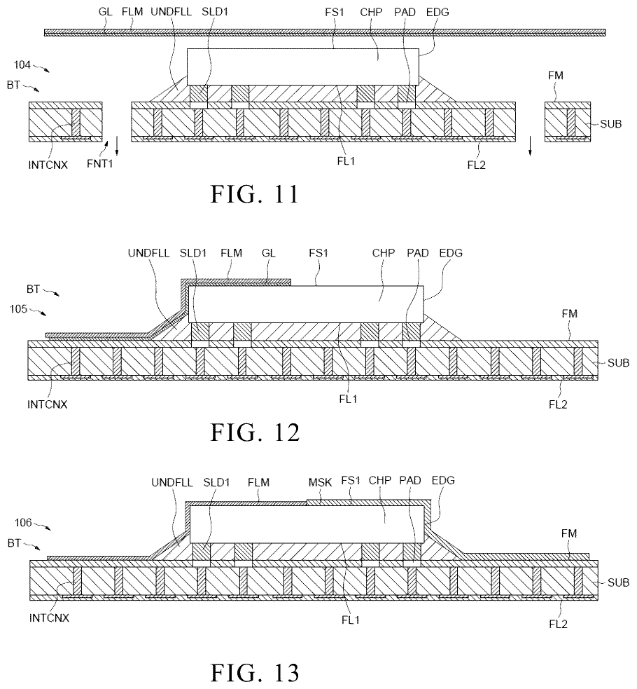

FIG. 11 illustrates a step 104 of forming an opening FNT1 and of attaching the thermally conductive film FLM as an alternative to steps 102 and 103 described above in relation with FIGS. 9 and 10.

The thermally conductive film FLM may be the same as that described above in relation with FIG. 9 and may be coated with glue or be attached to a double-sided adhesive tape for example.

The opening FNT1 passes through the thickness of the support plate SUB until opening onto the mounting face FM. The opening FNT1 is used to create a vacuum, for example thanks to a vacuum lamination technique known by the person skilled in the art, between the film FLM and the support plate SUB so that the film FLM covers the mounting face FM and seals the opening FNT1.

Vacuum lamination is a technique making it possible to attach the film FLM on the chip CHP so as to avoid the presence of air between the adhesive GL and the rear face FS1 of the chip and consequently improves the securing of the film FLM on the chip CHP.

Step 104 may be followed by a step of attaching weld beads SLD2 (not illustrated) on a face FL2 of the plate SUB opposite the mounting face FM to obtain the package BT shown in FIG. 3.

FIG. 12 illustrates a step 105 of attaching of the film FLM on a portion of the rear face FS1 of the chip CHP.

Step 105 is, preferably, performed after a step of identifying hot spots (not shown) of the chip CHP and a step of manufacturing the film FLM. The step of identifying hot spots of the chip CHP may be performed by thermal simulation of the chip CHP during operation or by thermal sensors.

The step of manufacturing the film FLM makes it possible to design a film FLM and to give it a shape making it possible for the film FLM to cover the hot spots of the chip CHP during the step 105 of attaching the film FLM. The attachment of the film FLM may be performed in a similar way to the attachment step 102 such as described in relation with FIG. 9.

Step 105 may be followed by a step of attaching weld beads SLD2 (not illustrated) on a face FL2 of the plate SUB opposite the mounting face FM and a step of attaching a heat sink (not illustrated) on the film FLM and the plate SUB to obtain the package BT shown in FIG. 4.

FIG. 13 illustrates a step 106 of chemical vapor deposition of the film FLM as an alternative to steps 102 and 105 described above in relation with FIGS. 9 and 12.

In particular, chemical vapor deposition makes it possible to form the film FLM, typically by sputtering, on the rear face FS1 and on the side faces EDG of the chip CHP.

Step 106 may also be performed by using a temporary mask MSK on the rear face FS1 and on the side faces EDG of the chip CHP.

In this way, the film FLM may only be formed on the portion of the rear face FS1 and on the side faces EDG of the chip CHP that are not covered by the mask MSK.

Step 106 may be followed by a step of removing the mask MSK, of attaching weld beads SLD2 (not illustrated) on a face FL2 of the plate SUB opposite the mounting face FM and a step of attaching a heat sink (not illustrated) on the film FLM and the plate SUB.

1. An integrated circuit package, including:
a support plate having a mounting face;
an electronic chip having a rear face and a front face, the front face of the electronic chip being mounted on and electrically connected to the mounting face of the support plate; and
a deformable thermally conductive film configured to cover and be in contact with at least one portion of the rear face of the electronic chip.

2. The package according to claim 1, wherein the deformable thermally conductive film is welded to at least one portion of the rear face of the electronic chip.

3. The package according to claim 1, wherein the deformable thermally conductive film is attached on at least one portion of the rear face of the electronic chip using an adhesive.

4. The package according to claim 3, wherein the support plate comprises an opening passing through a thickness of the support plate until reaching the mounting face, the deformable thermally conductive film further covering the mounting face and sealing said opening.

5. The package according to claim 1, further comprising a molding resin disposed on the mounting face of the support plate to encapsulate sides of the electronic chip and leave the rear face of the electronic chip uncovered by the molding resin, the deformable thermally conductive film also being configured to cover an upper face of the molding resin.

6. The package according to claim 1, wherein the electronic chip is configured to have hot spots releasing heat during operation, the deformable thermally conductive film being configured to cover the hot spots of the electronic chip.

7. The package according to claim 1, wherein the deformable thermally conductive film has a thickness between 5 μm and 0.5 mm.

8. The package according to claim 1, wherein the deformable thermally conductive film is a metal film.

9. The package according to claim 1, wherein a modulus of elasticity of the deformable thermally conductive film is between 10⁻⁵ and 100-150 Gpa.

10. The package according to claim 1, wherein the deformable thermally conductive film also covers the mounting face of the support plate and is connected to thermally conductive elements of the support plate.

11. The package according to claim 1, further comprising a component mounted on the mounting face of the support plate, wherein the deformable thermally conductive film also covers the mounting face of the support plate and comprises a further opening where the component is located.

12. The package according to claim 1, wherein the deformable thermally conductive film also covers at least one portion of a side face of the electronic chip which extends between the rear face and the front face.

13. The package according to claim 1, further comprising a heat sink mounted to the deformable thermally conductive film.

14. A method for manufacturing an integrated circuit package, comprising:
mounting an electronic chip to a mounting face of a support plate;
wherein the electronic chip has a rear face and a front face, and the front face is electrically connected to the mounting face; and
covering a portion of the rear face of the electronic chip by a deformable thermally conductive film so that the deformable thermally conductive film is in contact with the rear face.

15. The method according to claim 14, wherein covering the portion of the rear face by the deformable thermally conductive film comprises welding the deformable thermally conductive film on said portion of the rear face of the electronic chip.

16. The method according to claim 14, wherein covering the portion of the rear face by the deformable thermally conductive film comprises attaching the deformable thermally conductive film on at least one portion of the rear face of the electronic chip using an adhesive.

17. The method according to claim 16, comprising forming an opening passing through the thickness of the support plate until opening onto the mounting face, wherein covering comprises using the opening to create a vacuum between the deformable thermally conductive film and the support plate so that the deformable thermally conductive film covers the mounting face and seals said opening.

18. The method according to claim 14, wherein the deformable thermally conductive film has a thickness between 5 μm and 0.5 mm.

19. The method according to claim 14, wherein the deformable thermally conductive film is a metal.

20. The method according to claim 14, wherein a modulus of elasticity of the deformable thermally conductive film is between 10⁻⁵ and 100-150 Gpa.

21. The method according to claim 14, wherein covering the portion of the rear face by the deformable thermally conductive film comprises performing a chemical vapor deposition of the deformable thermally conductive film on at least one portion of the rear face of the electronic chip.

22. The method according to claim 14, comprising forming a molding resin on the mounting face of the support plate so that the molding resin encapsulates sides of the electronic chip and leaves the rear face uncovered, wherein the deformable thermally conductive film further covers an upper face of the molding resin.

23. The method according to claim 14, comprising identifying hot spots of the electronic chip by a thermal simulation of the electronic chip during operation, wherein the covering the portion of the rear face by the deformable thermally conductive film is performed so that the deformable thermally conductive film covers the hot spots of the electronic chip.

24. The method according to claim 14, further comprising connecting the deformable thermally conductive film to thermally conductive elements of the support plate.

25. The method according to claim 14, comprising mounting a component on the mounting face of the support plate and forming an opening in the deformable thermally conductive film at the location of the component.

26. The method according to claim 14, comprising covering a portion of the side face of the electronic chip by the deformable thermally conductive film at the same time as covering a portion of the rear face by the deformable thermally conductive film.

27. The method according to claim 14, further comprising mounting a heat sink to the deformable thermally conductive film.
